(19) United States
(12) Patent Application Publication
(10) Pub. No.: US 2025/0111713 A1
(43) Pub. Date: Apr. 3, 2025

(54) SYSTEM AND METHOD FOR DETECTING A MAINTENANCE PROBLEM IN A VEHICLE

(71) Applicant: V-HOLA Labs Ltd., Kfar Saba (IL)

(72) Inventors: Benjamin MAY, Lübs (DE); Sven FLECK, Sindelfingen (DE); Asaf TSIN, Kfar Saba (IL)

(73) Assignee: V-HOLA Labs Ltd., Kfar Saba (IL)

(21) Appl. No.: 18/833,075

(22) PCT Filed: Jan. 26, 2023
(86) PCT No.: PCT/IL2023/050088

§ 371 Date: Jul. 25, 2024

Related U.S. Application Data
(60) Provisional application No. 63/303,063, filed on Jan. 26, 2022.

(51) Int. Cl. G07C 5/08; G07C 5/02

(52) U.S. Cl. CPC G07C 5/0808; G07C 5/02

(57) ABSTRACT

A system and a method for detecting a maintenance problem in a vehicle are disclosed. The method comprising: receiving a temporal EM emission field at a plurality of locations inside the vehicle, when the vehicle is in use; receiving from database information related to a typical temporal EM emission field at the plurality of locations inside a reference vehicle; determining a deviation from the typical temporal EM emission field, and detecting a maintenance problem in the vehicle if the deviation is above a threshold value.

### CROSS REFERENCE TO RELATED APPLICATIONS

This application claims the benefit of priority under 35 U.S.C. § 119 (e) of U.S. Provisional Patent Application No. 63/303,063, filed Jan. 26, 2022, which is incorporated by reference as if fully set forth herein in its entirety.

### FIELD OF THE INVENTION

The present invention relates generally to a method for detecting a maintenance problem in a vehicle. More specifically, the present invention relates to a system and a method for detecting a maintenance problem in a vehicle based on electromagnetic (EM) emissions detected inside the vehicle.

### BACKGROUND OF THE INVENTION

Electric vehicles are the transportation means of the future. Electric and hybrid cars and trains are already run in millions on roads all over the world, and electric airplanes and ships are under development. These vehicles include many electrotechnical and electrical components that emit electromagnetic (EM) emissions.

Electrotechnical and electrical components age and wear with time, this will require maintenance (e.g., fixing and/or replacement). Some traveling conditions, such as frequent accelerations and/or slopy terrane can accelerate the wearing of the electrotechnical and electrical components. These aging and wearing conditions can affect the EM emission from the electrotechnical and electrical components, for example, by increasing or decreasing the EM emission levels emitted by the electrotechnical and electrical components.

Accordingly, the emitted EM emission levels can be used to detect maintenance problems in vehicles.

### SUMMARY OF THE INVENTION

Some aspects of the invention may be related to a system and a method for detecting a maintenance problem in a vehicle. The system may include a computing device configured to execute the following method steps comprising: receiving a temporal EM emission field at a plurality of locations inside the vehicle, when the vehicle is in use; receiving from database information related to a typical temporal EM emission field at the plurality of locations inside a reference vehicle; determining a deviation from the typical temporal EM emission field, and detecting a maintenance problem in the vehicle if the deviation is above a threshold value. In some embodiments, the system may include one or more EM sensing units for providing measurements indicative of the temporal EM emission field.

In some embodiments, the information related to the typical temporal EM emission is determined based on information gathered from the vehicle during a predetermined operation time. In some embodiments, the information related to the typical temporal EM emission is determined based on information gathered from the vehicle during a test. In some embodiments, the information related to the typical temporal EM emission is determined based on information gathered from a group of vehicles having at least one similar property to the vehicle. In some embodiments, the at least one similar property is selected from, a model of the vehicle, a size of an engine/motor, an age of the vehicle or of vehicle components, a kilometrage, a vehicle type (e.g., passenger vehicle, truck, electric bike, train, airplane, drone, ship, scooter, maglev train, elevator, moving stairway, roller conveyor), a manufacturer, a variant of the vehicle, an architecture of the vehicle (e.g., within OEM or cross-OEM), a performance summary of the vehicle's powertrain (e.g., acceleration, maximum velocity, weight, etc.), a powertrain configuration (e.g., single/dual/triple/quadruple/motors, electrical vs. hybrid, transmission gears and gear ratios, etc.), a seat configuration, a configuration of electrical motors (e.g., number of motors, locations/layout, type, technology (e.g., DC vs. AC, AC synchronous reluctance motor, etc.), power, torque, peak power, peak torque per motor), an age of the vehicle, a kilometrage, a battery configuration (e.g., capacity, charging capability, battery cell technology, voltage, maximum current, etc.), an in-vehicle charger configuration (e.g., charging capability DC/AC, power, wired vs. wireless/inductive, etc.), a range information.

In some embodiments, the information is gathered from the group of vehicles during operation. In some embodiments, the information is gathered from the group of vehicles during tests. In some embodiments, the information is gathered from simulation or data inference based on at least one similar property to the vehicle.

In some embodiments, the method further comprises receiving temporal driving conditions associated with the temporal EM emission field and selecting from the received information related to the typical temporal EM emission field information gathered at similar temporal driving conditions. In some embodiments, the temporal driving conditions are selected from, an acceleration of the vehicle, a velocity of the vehicle, a slope of a road, a deceleration/recuperation of the vehicle, a charging profile (e.g., current), a spatial location (GPS position), a loading situation, a vehicle seat occupancy configuration, a charging mode, a charging principle (wired vs. inductive/wireless), a charging power, a charging current, an environmental conditions (e.g., temperature, humidity, altitude, etc.), a battery property (e.g., actual voltage, temperature, etc.), powertrain temperature, a motor stator temperature, any information available on a vehicle bus or network.

In some embodiments, the method further comprises determining one or more locations in the vehicle at which a deviation from the typical temporal EM emission field was determined; and assessing at least one of a type and a location of the maintenance problem. In some embodiments, the method further comprises predicting a trend of deviation from the typical temporal EM emission field and assessing at least one of a type and a location of the maintenance problem.

In some embodiments, the method further comprises determining a level of the deviation from typical temporal EM emission field; and assessing the severity of the maintenance problem based on the level of deviation or on a level of deviation of first-order or higher-order temporal derivatives of the level of deviation.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a block diagram, depicting a computing device which may be included in a system according to some embodiments of the invention;

FIG. 2 is a block diagram, depicting a system for detecting a maintenance problem in a vehicle according to some embodiments of the invention;

FIG. 3 is a flowchart of a method of detecting a maintenance problem in a vehicle;

FIG. 4 is an illustration of a virtual 3D mesh of a passengers' cabin of a vehicle according to some embodiments of the invention; and

FIG. 5 is an illustration of a histogram of EM emission amplitude at various frequencies measured at a location in the vehicle according to some embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

One skilled in the art will realize the invention may be embodied in other specific forms without departing from the spirit or essential characteristics thereof. The foregoing embodiments are therefore to be considered in all respects illustrative rather than limiting of the invention described herein. The scope of the invention is thus indicated by the appended claims, rather than by the foregoing description, and all changes that come within the meaning and range of equivalency of the claims are therefore intended to be embraced therein.

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention. Some features or elements described with respect to one embodiment may be combined with features or elements described with respect to other embodiments. For the sake of clarity, discussion of same or similar features or elements may not be repeated.

Although embodiments of the invention are not limited in this regard, discussions utilizing terms such as, for example, “processing,” “computing,” “calculating,” “determining,” “establishing”, “analyzing”, “checking”, “estimating”, “inferring”, or the like, may refer to operation(s) and/or process(es) of a computer, a computing platform, a computing system, or another electronic computing device, that manipulates and/or transforms data represented as physical (e.g., electronic) quantities within the computer's registers and/or memories into other data similarly represented as physical quantities within the computer's registers and/or memories or other information non-transitory storage medium that may store instructions to perform operations and/or processes.

Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. The term set when used herein may include one or more items. Unless explicitly stated, the method embodiments described herein are not constrained to a particular order or sequence. Additionally, some of the described method embodiments or elements thereof can occur or be performed simultaneously, at the same point in time, or concurrently.

The term set when used herein can include one or more items. Unless explicitly stated, the method embodiments described herein are not constrained to a particular order or sequence. Additionally, some of the described method embodiments or elements thereof can occur or be performed simultaneously, at the same point in time, or concurrently.

Embodiments of the present invention disclose a method and a system for detecting a maintenance problem in a vehicle. Electrical, electronic, and electromechanical components in a vehicle emit EM emission when in use. Each component may exhibit typical EM emissions under typical driving conditions. A deviation from these typical EM emissions may be indicative of a maintenance problem in the component.

Since a slight deviation from typical EM emissions may be detected already at the first stages of the maintenance problem, detection of the deviation may prevent an occurrence of a critical maintenance problem. In some embodiments, the amount and/or location of the EM emission may be indicative of the type and the severity of the maintenance problem.

In some embodiment, a prediction of the deviation from typical EM emissions may be performed to enable earlier alarm by looking not only at the actual EM emission but at its derivatives too. Alternatively, regression techniques can be used to fit a function to EMF over time, of which derivatives can be computed thereof. Optionally, a filter shall be applied first to reduce noise that affects derivatives (low pass). In some embodiments, an alternative view on this extension includes a simple PID control that has P, I, and D inputs instead of P alone (“the difference to limit”).

The electrical, electronic, and electromechanical components of the vehicle may include, for example, the vehicle's electric motor, the vehicle's battery, the vehicle's electric wires, the vehicle's computer, the vehicle's power inverters, the vehicle's relay switches, the vehicle's radiofrequency (RF) components, autonomous vehicle's processor, integrated or standalone (aftermarket) product, and the like.

As used herein, a “vehicle” may be any form of transportation that includes one or more EM radiating components. For example, a vehicle may be, an electric car, a hybrid car, an electric bus, an electric train, an electric ship, an electric airplane, an electric drone, an electric bike, an electric scooter, a maglev train, an elevator, a moving stairway, a roller conveyor, a treadmill, and the like. A “vehicle” may alternatively be any form of enclosure a human may be in, including for fitness or medical reasons. For example, an MRI scanner.

As used herein, an “EM emission” may refer to the entire EM spectrum. More specifically, the EM emission may refer to several more specific spectrums, for example, ultraviolet (UV) 3-30 PHz, infrared (IR) 300 GHz-3 PHz, spectrums included in the radiofrequency (RF) spectrum (3 Hz-300 GHz), such as extremely low frequency (ELF) 3-30 Hz, supper low frequency (SLF) 30-300 Hz, ultra-low frequency (ULF) 300-3 KHz, RF broadcasting bands 3 KHz-300 GHz and the like.

As used herein, a “radiating component” may be any component of the vehicle that radiates EM emission (at any spectrum). Some examples, so for radiating components radiating EM emission at the ELF may include: the vehicle's electric motor, the vehicle's battery, the vehicle's electric wires, at least one of the vehicle's computers (e.g., an HPC architecture of electrical vehicles), the vehicle's power inverters, the vehicle's relay switches and the like. Additional examples, of radiating components radiating EM emission at the wireless RF range, may include, the vehicles' Bluetooth communication device, a GPS antenna, a cellular radio module, a Wi-Fi radio module, and the like.

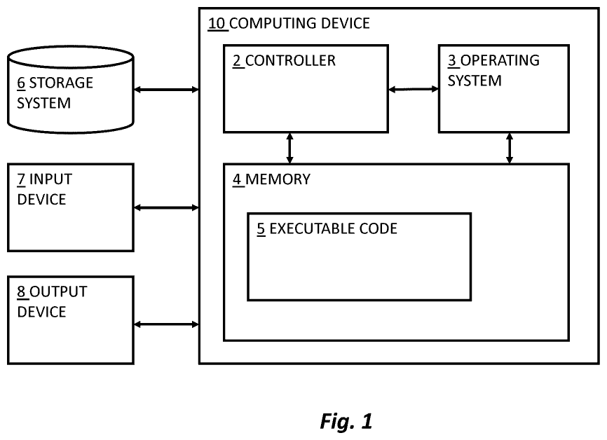

Reference is now made to FIG. 1, which is a block diagram depicting a computing device, which may be included within a system for detecting a maintenance problem in a vehicle, according to some embodiments. A computing device, such as device 10 may be included in the vehicle's computing system. In some embodiments, more than one computing device 10 may be included in the vehicle's computing system.

Computing device 10 may include a controller 2 that may be, for example, a central processing unit (CPU) processor, a chip or any suitable computing or computational device, an operating system 3, a memory 4, executable code 5, a storage system 6, input devices 7 and output devices 8. Controller 2 (or one or more controllers or processors, possibly across multiple units or devices) may be configured to carry out methods described herein, and/or to execute or act as the various modules, units, etc. More than one computing device 10 may be included in, and one or more computing devices 10 may act as the components of, a system according to embodiments of the invention.

Operating system 3 may be or may include any code segment (e.g., one similar to executable code 5 described herein) designed and/or configured to perform tasks involving coordination, scheduling, arbitration, supervising, controlling, or otherwise managing the operation of computing device 10, for example, scheduling execution of software programs or tasks or enabling software programs or other modules or units to communicate. Operating system 3 may be a commercial operating system. It will be noted that an operating system 3 may be an optional component, e.g., in some embodiments, a system may include a computing device that does not require or include an operating system 3.

Memory 4 may be or may include, for example, a Random Access Memory (RAM), a read-only memory (ROM), a Dynamic RAM (DRAM), a Synchronous DRAM (SD-RAM), a double data rate (DDR) memory chip, a Flash memory, a volatile memory, a non-volatile memory, a cache memory, a buffer, a short term memory unit, a long term memory unit, or other suitable memory units or storage units. Memory 4 may be or may include a plurality of, possibly different memory units. Memory 4 may be a computer or processor non-transitory readable medium, or a computer non-transitory storage medium, e.g., a RAM. In one embodiment, a non-transitory storage medium such as memory 4, a hard disk drive, a solid-state disk, a flash memory, another storage device, etc. may store instructions or code which when executed by a processor may cause the processor to carry out methods as described herein.

Executable code 5 may be any executable code, e.g., an application, a program, a process, task, or script. Executable code 5 may be executed by controller 2 possibly under the control of operating system 3. For example, executable code 5 may be an application that may detect a maintenance problem in a vehicle as further described herein. Although, for the sake of clarity, a single item of executable code 5 is shown in FIG. 1, a system according to some embodiments of the invention may include a plurality of executable code segments similar to executable code 5 that may be loaded into memory 4 and cause controller 2 to carry out methods described herein.

Storage system 6 may be or may include, for example, a flash memory as known in the art, a memory that is internal to, or embedded in, a microcontroller or chip as known in the art, a hard disk drive, a CD-Recordable (CD-R) drive, a Blu-ray disk (BD), a universal serial bus (USB) device or other suitable removable and/or fixed storage unit. For example, parameters of the vehicle, (virtual) meshing of the vehicle, the location of EM sensing units, and/or the locations of radiating components may be stored in storage system 6 and may be loaded from storage system 6 into memory 4 where it may be processed by controller 2. In some embodiments, some of the components shown in FIG. 1 may be omitted. For example, memory 4 may be a non-volatile memory having the storage capacity of storage system 6. Accordingly, although shown as a separate component, storage system 6 may be embedded or included in memory 4. In some embodiments, storage system 6 may be a cloud base storage system.

Input devices 7 may be or may include any suitable input devices, components, or systems, e.g., a detachable keyboard or keypad, a mouse, and the like. Output devices 8 may include one or more (possibly detachable) displays or monitors, speakers, and/or any other suitable output devices. Any applicable input/output (I/O) devices may be connected to Computing device 10 as shown by blocks 7 and 8. For example, a wired or wireless network interface card (NIC), a universal serial bus (USB) device, or an external hard drive may be included in input devices 7 and/or output devices 8. It will be recognized that any suitable number of input devices 7 and output device 8 may be operatively connected to Computing device 1 as shown by blocks 7 and 8.

A system according to some embodiments of the invention may include components such as, but not limited to, a plurality of central processing units (CPU) or any other suitable multi-purpose or specific processors or controllers (e.g., controllers similar to controller 2), a plurality of input units, a plurality of output units, a plurality of memory units, and a plurality of storage units.

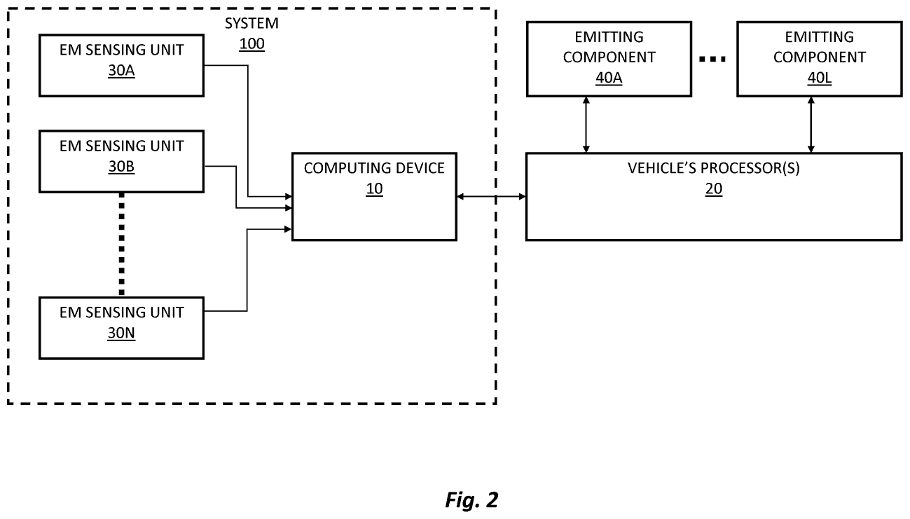

Reference is now made to FIG. 2, which is a block diagram of a system for detecting a maintenance problem in a vehicle according to some embodiments of the invention. A system such as a system 100 may include a computing device 10 that may be in communication with one or more of the vehicle's processors 20, for example, via I/O devices 7 and 8. In some embodiments, system 100 may include or may be in communication with one or more EM sensing units 30A-30N. As should be understood by one skilled in the art the three sensing units illustrated in FIG. 2 are given as an example only and any number of EM sensing units can be included in the invention. In some embodiments, EM sensing units 30A-30N may communicate with computing device 10 via either wired and/or wireless communication using any known protocol (e.g., LAN, Bluetooth, and the like).

In some embodiments, EM sensing units 30A-30N may include any sensing unit configured to detect an emission vector of an EM field generated by a component of the vehicle (e.g., a first EM emission vector). In some embodiments, units 30A-30N may each include a single EM sensor configured to measure a 3D EM field (e.g., a magnetic field). In some embodiments, units 30A-30N may each include 3 EM sensors, each configured to measure an EM field (e.g., magnetic field) in a single direction. In such embodiments, the EM sensors may be assembled orthogonal to each other, each configured to measure EM field (e.g., a magnetic field) in a specific direction orthogonal to the direction of the field measured by the two other EM sensors. For example, the sensors may be Anisotropic Magneto-resistive (AMR) sensors, such as Honeywell HMC104, available from Honeywell, Hall Effect sensors, such as DRV5053 available from Texas, Instruments, and the like.

In some embodiments, EM sensing units 30A-30N may be assembled at the closest assembling location to each radiating component. For example, a sensing unit 30A may be assembled on the envelope of the vehicle's electric motor. In another example, a sensing unit 30B may be attached to a wire of the vehicle. In yet another example, a sensing unit 30C may be attached to the Bluetooth device of the vehicle.

In some embodiments, the vehicle may include a plurality of vehicle processors 20, and system 100 may communicate with at least one vehicle processor 20, which may be a computing device, such as computing device 10.

In some embodiments, emitting components 40A-40L may be any component of the vehicle that radiates EM emission (at any spectrum). Some examples of radiating components radiating EM emission may include the vehicle's electric motor, the vehicle's battery, the vehicle's electric wires, at least one of the vehicle's computers 20, the vehicle's power inverters, the vehicle's relay switches, the vehicle's audio or multimedia system, a Bluetooth communication device, a GPS antenna, and the like.

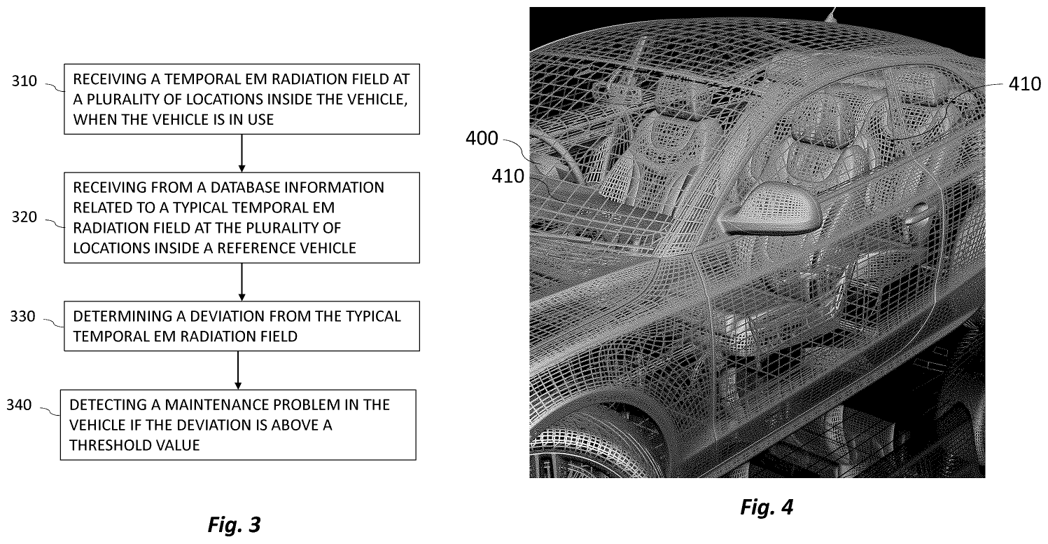

Reference is now made to FIG. 3 which is a flowchart of a method of detecting a maintenance problem in a vehicle, according to some embodiments of the invention. The method of FIG. 3 may be performed by system 100 under the control/supervision of computing device 10.

In step 310, a computing device, such as computing device 10, may reactive a temporal EM emission field at a plurality of locations inside the vehicle, when the vehicle is in use. In some embodiments, the temporal EM emission field may be received during the traveling of the vehicle at various traveling conditions. In some embodiments, computing device 10 may correlate between the received temporal EM emission field and the traveling conditions at which the temporal EM emission field was received. Some examples for such traveling conditions include traveling at a specific acceleration, traveling at a substantially constant speed, traveling on a sloppy road at a specific slop, and the like. In some embodiments, computing device 10 may receive the traveling conditions from, one or more of the vehicle's processors 20, a map of the road, GNSS sensor, and the like.

In some embodiments, the temporal EM emission field may include at least one EM emission vector determined for at least one location inside the vehicle. In some embodiments, the at least one EM emission vector may include the magnetic flux density vector field of the EM emission over time. In some embodiments, the at least one EM vector, may be determined from one or more EM emission sensors located in various locations in the vehicle. For example, at least one EM sensing unit 30A may be placed, in proximity to emitting element 40A, under the driver's seat, under the front passenger seat, under the passenger back seat, and the like. In some embodiments, direct measurement of the EM emission from emitting component 40A is conducted when EM sensing unit 30A is located in proximity to emitting component 40A.

In some embodiments, determining the EM emission is done by calculating the EM emission from measurements received from a plurality of EM sensing units located at known locations in the vehicle. For example, sensing units 30A-30N may be located in proximity or at least some of the EM emitting components of the vehicle, as discussed hereinabove, and the EM emission is calculated by vector addition of all EM emission vectors, measured by sensing units 30A-30N, directed to the at least one location.

In some embodiments, computing device 10 may calculate the accumulated first EM emission at one or more locations in the vehicle using vector addition.

In some embodiments, determining the at least EM vector is by calculating the EM vector from information related to EM emitting components of the vehicle and/or of the vehicle-related component. In some embodiments, the information comprises, for each emitting component, at least one of a current, a voltage, a power, and a location of the component in or in proximity relative to the vehicle. For example, computing device 10 may receive from one or more vehicle computers 20 operation parameters (e.g., the current flowing in, to, or from an electric component) of at least one emitting component 40A-40M, in real-time. In some embodiments, computing device 10 may be configured to calculate indications related to emission vectors of EM field based on the received operation parameters, for example, by calculating the size and direction of the magnetic field using equation (1):

$$\vert {\vec{B}}_{j} \vert = \vert \frac{{μ}_{0} \vec{ι}}{2 π r} \vert \qquad ( 1 )$$

Wherein, \vec{B} is the EM emission vector (e.g., the magnetic field vector) generated by emission component j (j=1 to M), i is the current flowing in, to/or from an electric component and r the distance from the radiating component.

In some embodiments, receiving the one or more indications may be conducted at predetermined time intervals. For example, one or more indications may be received form sensing units 30A-30N or may be calculated every several seconds, for example, every 0.1, 0.5, 1, 2, 3, or 4 seconds.

In some embodiments, a 3D mesh of locations within the vehicle may be received, for example, from the vehicle's manufacturers, for example, mesh 400 illustrated in FIG. 4, or may be calculated based on the vehicle's parameters. In some embodiments, the mesh and/or vehicle's parameters may be stored in a database, for example, storage system 6.

In some embodiments, device 10 may identify in the mesh one or more nodes 410, which are defined as points on the mesh located at the intersection of two or more mesh lines. Each node is located at a specific known location in the vehicle. Therefore, computing device 10 may identify nodes located in proximity to one or more emitting components 40A-40M.

In some embodiments, computing device 10 may calculate the distance of each identified node from each sensing unit 30A and/or emitting components 40A-40M. In some embodiments, computing device 10, may use the distance as “r” in equation (1) to calculate the size of the magnetic field generated by each emitting component 40A-40M at a certain node.

In some embodiments, computing device 10 may adjust the readings received from one or more sensing units 30A-30N based on the distance between each sensing unit and the node using for example, equation (1). Computing device 10 may receive the distance between a sensing unit and the closest radiating element, and the distance from the radiating element to the node.

In some embodiments, the EM field of at least one node of the 3D mesh may be calculated by vector addition of the emission vectors of the EM fields at the node's location. For example, for at least one node all the magnetic field vectors calculated for each emitting components 40A-40M may be summed, using equation (2).

$$\vec{{B}_{n o d e}} = {\sum }_{M}^{1} {B}_{j} \qquad ( 2 )$$

In some embodiments, device 10 may form and display (e.g., via output device 8) a 3D map (e.g., a heat-map) of the emission levels at various locations in the vehicle. In some embodiments, the 3D maps may be stored in a database, for example, on the cloud-based storing service.

In some embodiments, determining the first EM emission vector may further include determining at least one frequency and at least one corresponding phase.

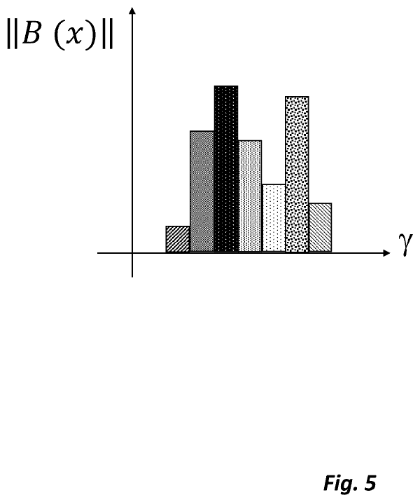

In some embodiments, the method may include, for an identified location (e.g., a node located at a high importance location) identifying a plurality of frequencies in the first EM emission vector and determining an intensity/amplitude and a phase for each frequency, for example, as illustrated in FIG. 5. FIG. 5 is an illustration of a histogram of EM emission amplitude B(x) at various frequencies y measured at a location in the vehicle according to some embodiments of the invention. As shown in FIG. 5, at a specific location, the EM emission vector may include a superposition of EM emission vectors having different frequencies and corresponding amplitudes.

In some embodiments, the method may include creating for each location from a plurality of locations a frequency-dependent histogram of the EM emission intensities. For example, for each node (e.g., located at a high importance location) computing device 10 may create a histogram, such as the histogram of FIG. 5.

Referring back to FIG. 3, in step 320, computing device 10 may receive from database information related to a typical temporal EM emission field at the plurality of locations inside a reference vehicle. For example, computing device 10 may receive from storage system 6 and/or from an external database the typical temporal EM emission field at the plurality of locations inside a reference vehicle. In some embodiments, the typical temporal EM emission field may be correlated to a specific traveling condition, as disclosed hereinabove with respect to step 310.

In some embodiments, the information related to the typical temporal EM emission is determined based on information gathered from the vehicle during a predetermined operation time. For example, computing device 10 may collect over a predetermined time, for example, at least 6 months, temporal EM emission at various locations if the vehicle. In some embodiments, the temporal EM emission may be further be associated with specific traveling conditions and may be stored in a storage system 6.

Computing device 10 may sort the temporal EM emission into groups according to their associated traveling conditions. For example, all the temporal EM emissions gathered when the vehicle accelerates at substantially (e.g., ±5%) the same acceleration may be sorted into the same group. In yet another example, all the temporal emissions gathered when traveling on a road having substantially similar slop (e.g., ±5° may be sorted into the same group. In some embodiment, the average temporal EM emission of each group is the typical temporal EM emission at a location in the vehicle at specific traveling conditions. For example, a histogram with discrete EM emission bins is used.

In some embodiments, robust statistics mechanisms are utilized to filter irrelevant information (noise) yet estimate current deviation of EM emission. This includes, but is not limited to running median, running average and other estimation approaches that are robust against outliers, including maximum likelihood estimators (MLEs).

In some embodiments, the information related to the typical temporal EM emission is determined based on information gathered from the vehicle during a test. For example, the vehicle may enter a testing station (e.g., in the OEM's premises) at which different traveling conditions may be simulated in a controlled environment. In some embodiments, the temporal EM emission gathered during these tests at various locations in the vehicle is set as the typical temporal EM emission.

In some embodiments, the information related to the typical temporal EM emission is determined based on information gathered from a group of vehicles having at least one similar property to the vehicle. In some embodiments, vehicles having similar properties are expected to have substantially the same mechanical and electrical behavior. In some embodiments, the at least one similar property is selected from, a model of the vehicle, the size of the engine, age of the vehicle, a kilometrage, and the like. For example, vehicles from the same OEM, having the same engine and gear units are expected to have similar temporal EM emission at the same traveling or testing conditions.

In some embodiments, the information is gathered from the group of vehicles during operation. For example, the information may be associated with a specific road and may be gathered from the group of vehicles that traveled on the road. In some embodiments, the information may be received in real-time, for example, from all the vehicles in the group traveled on the specific road on the same day, week, month, etc.

In some embodiments, computing device 10 may receive temporal driving conditions associated with the temporal EM emission field, and select from the received information related to the typical temporal EM emission field information gathered at similar temporal driving conditions. In some embodiments, the temporal driving conditions are selected from, an acceleration of the vehicle, a velocity of the vehicle, a slope of a road and the like.

In some embodiments, the information is gathered from the group of vehicles during tests. For example, the information may be collected from tests conducted on similar vehicles in a testing station.

In step 330, computing device 10 may determine a deviation from the typical temporal EM emission field. This may include detection of anomalies in EM emission field.

In step 340, computing device 10 may detect a maintenance problem in the vehicle if the deviation is above a threshold value. In some embodiments, computing device 10 may determine one or more locations in the vehicle at which a deviation from the typical temporal EM emission field was determined and assess at least one of a type and a location of the maintenance problem. In some embodiments, the map of EM emission vectors may show deviation from the typical temporal EM emission field in proximity to specific components. In some embodiments, each component of the vehicle may be associated with a different predetermined threshold. For example, more critical components, such as an engine may be associated with smaller allowed deviation from the typical temporal EM emission field than less critical components such as the vehicle's audio system. In some embodiments, computing device 10 may assess a severity of the maintenance problem based on the level of deviation, for example, the higher the level of deviation the more severe the maintenance problem.

Unless explicitly stated, the method embodiments described herein are not constrained to a particular order or sequence. Furthermore, all formulas described herein are intended as examples only and other or different formulas may be used. Additionally, some of the described method embodiments or elements thereof may occur or be performed at the same point in time.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

Various embodiments have been presented. Each of these embodiments may of course include features from other embodiments presented, and embodiments not specifically described may include various features described herein.

1. A method for detecting a maintenance problem in a vehicle, comprising:
receiving a temporal EM emission field at a plurality of locations inside the vehicle, when the vehicle is in use;
receiving from database information related to a typical temporal EM emission field at the plurality of locations inside a reference vehicle;
determining a deviation from the typical temporal EM emission field; and
detecting a maintenance problem in the vehicle if the deviation is above a threshold value.

2. The method of claim 1, wherein the information related to the typical temporal EM emission is determined based on information gathered from the vehicle during a predetermined operation time.

3. The method of claim 1, wherein the information related to the typical temporal EM emission is determined based on information gathered from the vehicle during a test.

4. The method of claim 1, wherein the information related to the typical temporal EM emission is determined based on information gathered from a group of vehicles having at least one similar property to the vehicle.

5. The method of claim 4, wherein the at least one similar property is selected from, a model of the vehicle, a size of the engine, age of the vehicle, a kilometrage, a vehicle type, a manufacturer, a variant of the vehicle, an architecture of the vehicle, a performance summary of the vehicle's powertrain, a powertrain configuration, a seat configuration, a configuration of electrical motors a battery configuration an in-vehicle charger configuration, and a range information.

6. The method of claim 4, wherein the information is gathered from the group of vehicles during operation.

7. The method of claim 4, wherein the information is gathered from the group of vehicles during tests.

8. The method according to claim 1, further comprising:
receiving temporal driving conditions associated with the temporal EM emission field; and
selecting from the received information related to the typical temporal EM emission field information gathered at similar temporal driving conditions.

9. The method of claim 8, wherein the temporal driving conditions are selected from, an acceleration of the vehicle, a velocity of the vehicle, a slope of a road, a deceleration or a recuperation of the vehicle, a charging profile, a spatial location, a loading situation, a vehicle seat occupancy configuration, a charging mode, a charging principle, a charging power, a charging current, an environmental/Conditions, battery property, including actual voltage, temperature, powertrain temperature, a motor stator temperature, any information available on a vehicle bus/network.

10. The method according to claim 1, further comprising:
determining one or more locations in the vehicle at which a deviation from typical temporal EM emission field was determined; and
assessing at least one of: a type and a location of the maintenance problem.

11. The method according to claim 1, further comprising:
determining a level of the deviation from typical temporal EM emission field; and
assessing a severity of the maintenance problem based on the level of deviation or on a level of deviation of first order or higher order temporal derivatives of the level of deviation.

12. A system for detecting a maintenance problem in a vehicle, comprising:
one or more electromagnetic sensing units; and
a computing device configured to:
receive a temporal EM emission field at a plurality of locations inside the vehicle from the one or more electromagnetic sensing units, when the vehicle is in use;
receive from database information related to a typical temporal EM emission field at the plurality of locations inside a reference vehicle;
determine a deviation from the typical temporal EM emission field; and
detect a maintenance problem in the vehicle if the deviation is above a threshold value.

13. The system of claim 12, wherein the information related to the typical temporal EM emission is determined based on information gathered from the vehicle during a predetermined operation time.

14. The system of claim 12, wherein the information related to the typical temporal EM emission is determined based on information gathered from the vehicle during a test.

15. The system of claim 12, wherein the information related to the typical temporal EM emission is determined based on information gathered from a group of vehicles having at least one similar property to the vehicle.

16. The system of claim 15, wherein the at least one similar property is selected from, a model of the vehicle, a size of the engine, age of the vehicle, a kilometrage, a vehicle type, a manufacturer, a variant of the vehicle, an architecture of the vehicle, a performance summary of the vehicle's powertrain, a powertrain configuration, a seat configuration, a configuration of electrical motors a battery configuration an in-vehicle charger configuration, and a range information.

17. The system of claim 15, wherein the information is gathered from the group of vehicles during operation.

18. The system of claim 15, wherein the information is gathered from the group of vehicles during tests.

19. The system according to claim 12, wherein the computing device is further configured to:
receive temporal driving conditions associated with the temporal EM emission field; and
select from the received information related to the typical temporal EM emission field information gathered at similar temporal driving conditions.

20. The system of claim 19, wherein the temporal driving conditions are selected from, an acceleration of the vehicle, a velocity of the vehicle, a slope of a road, a deceleration or a recuperation of the vehicle, a charging profile, a spatial location, a loading situation, a vehicle seat occupancy configuration, a charging mode, a charging principle, a charging power, a charging current, an environmental/Conditions, battery property, including actual voltage, temperature, powertrain temperature, a motor stator temperature, any information available on a vehicle bus/network.

21.-22. (canceled)
